(19) United States
(12) Patent Application Publication
(10) Pub. No.: US 2026/0293496 A1
(43) Pub. Date: Sep. 24, 2026

(54) ELASTIC MEMBER AND DISPLAY DEVICE COMPRISING SAME

(71) Applicant: LG INNOTEK CO., LTD., Seoul (KR)

(72) Inventors: Sung Won KANG, Seoul (KR); Joon Hyuk YANG, Seoul (KR); Jong Min LEE, Seoul (KR)

(21) Appl. No.: 19/476,760

(22) PCT Filed: May 3, 2024
(86) PCT No.: PCT/KR2024/006024

§ 371 Date: Oct. 20, 2025

(30) Foreign Application Priority Data
May 3, 2023 (KR) 10-2023-0058033

(51) Int. Cl. H10K 59/80; H10K 102/00

(52) U.S. Cl. CPC H10K 59/873; H10K 2102/311

(57) ABSTRACT

An elastic member according to an embodiment includes a first layer including a plurality of edges, wherein at least one edge among the plurality of edges is an bent edge, the first layer includes a first region corresponding to the bent edge and a second region inside the plurality of edges surrounded by the plurality of edges, and the first region is provided with a plurality of pattern parts in which at least a part of the first layer is opened from one surface of the first layer toward the other surface of the first layer.

### TECHNICAL FIELD

An embodiment relates to an elastic member and a display device including the same.

### BACKGROUND ART

Recently, there has been a growing demand for display devices that are portable and capable of displaying images on a large screen.

To achieve this, these display devices are formed in various shapes. For example, one region of the display device may be bendable. Alternatively, one region of the display device may be foldable.

For example, flexible display devices, foldable display devices, slidable display devices, or rollable display devices are being used.

In these display devices, one region may be bent, folded, or rolled. Consequently, the display device includes a region with a curvature. Accordingly, cracks may occur in the region. Alternatively, a crease may occur in the region.

This can reduce the reliability of the display device.

Therefore, a new structure of elastic member capable of solving the problems is required.

Meanwhile, Korean Patent Publication No. KR10-2018-0079091 (Jul. 10, 2018) is disclosed as a prior art related to elastic members.

### DISCLOSURE

### Technical Problem

An embodiment provides an elastic member with improved folding characteristics.

The embodiment provides a display device having various designs.

### Technical Solution

An elastic member according to an embodiment comprises a first layer including a plurality of edges, wherein at least one edge among the plurality of edges is an bent edge, wherein the first layer includes a first region corresponding to the bent edge and a second region inside the plurality of edges surrounded by the plurality of edges, and the first region is provided with a plurality of pattern parts in which at least a part of the first layer is opened from one surface of the first layer toward the other surface of the first layer.

In addition, the elastic member further comprises a second layer disposed on the first layer; and a third layer disposed on the second layer.

In addition, the first region includes a first-first region and a first-second region, depending on a distance from a first end of the bent edge, the first-first region is located further from the first end than the first-second region, and the first layer is bent in at least one of the first-first region and the first-second region.

In addition, the pattern part is provided in the first-first region.

In addition, a width of the first-first region and a width of the first-second region are different.

In addition, the first-first region is spaced apart from the first end in a first direction with the first-second region interposed therebetween, the first-first region includes a second end and a third end positioned in a second direction different from the first direction, and the first-first region includes a hinge part in which at least one of the second end and the third end is open.

In addition, the pattern part is formed by penetrating at least 50% of the first layer.

In addition, the second region includes a second-first region and a second-second region, the second-first region is positioned between a plurality of second-second regions, the first-first region includes a first pattern part, and the second-first region includes a second pattern part.

In addition, a ratio of an area of the second pattern part to an total area of the second-first region is greater than a ratio of an area of the first pattern part to an total area of the first-first region.

In addition, a second-first pattern part is disposed in the second-first region, a second-second pattern part is disposed in the second-second region, and a size of the second-second pattern part decreases as it moves away from the second-first region.

In addition, the second region includes a second-first region and a second-second region, the second-first region is defined as a sliding region, a first pattern part is disposed in the first-first region, and a second pattern part is disposed in the second-first region.

In addition, a ratio of an area of the second pattern part to a total area of the second-first region is greater than a ratio of an area of the first pattern part to a total area of the first-first region.

In addition, the second region is defined as a rolling region, a first pattern part is disposed in the first-first region, and a second pattern part is disposed in the second region.

In addition, a ratio of an area of the second pattern part to a total area of the second-first region is greater than a ratio of an area of the first pattern part to a total area of the first-first region.

### Advantageous Effects

An elastic member according to a first embodiment includes a bendable region. Specifically, an edge region of the elastic member is bent. That is, the elastic member includes a first region that is bent.

The pattern part is formed in the first region. A reaction force of the first region is reduced by the pattern part. Accordingly, a force acting in an opposite direction of a bending direction of the first region is reduced.

Therefore, the stress generated in the first region is reduced. Accordingly, the adhesion between the first layer and the second layer is improved. Furthermore, a bent shape of the first region is maintained. Therefore, the reliability of the elastic member is improved. Furthermore, the design freedom of the elastic member is enhanced.

An elastic member according to a second embodiment includes a bendable region and a foldable region. Specifically, the elastic member includes a folding region. Accordingly, the elastic member is applied to a foldable display device.

In detail, an edge region of the elastic member is bent. That is, the elastic member includes a first region that is bent. In addition, an inner region of the elastic member is foldable. That is, the elastic member includes a second region that is folded.

The first pattern part is formed in the first region. The reaction force of the first region is reduced by the first pattern part. Accordingly, the force acting in an opposite direction of a bending direction of the first region is reduced.

Furthermore, the second pattern part is formed in the second region. The stress of the second region is reduced by the second pattern part. Accordingly, the second region is easily folded.

Furthermore, ratios of pattern parts formed in the first region and the second region are different. Specifically, a ratio of the second pattern part formed in the second region is greater than a ratio of the first pattern part formed in the first region.

Therefore, the folding characteristics and strength of the elastic member can be improved.

An elastic member according to a third embodiment includes a foldable region and a bendable region. That is, the elastic member includes a sliding region. Accordingly, the elastic member is applied to a slidable display device.

In detail, an edge region of the elastic member is bent. That is, the elastic member includes a first region that is bent. Furthermore, one region of the elastic member is slid. That is, the elastic member includes a second region that is slid.

The first pattern part is formed in the first region. The reaction force of the first region is reduced by the first pattern part. Accordingly, the force acting in an opposite direction to a bending direction of the first region is reduced.

Furthermore, the second pattern part is formed on the second region. The stress of the second region is reduced by the second pattern part. Accordingly, the second region is easily slidable.

Furthermore, ratios of the pattern parts formed on the first region and the second region are different. Specifically, the ratio of the second pattern part formed in the second region is greater than the ratio of the first pattern part formed in the first region.

Therefore, the sliding characteristics and strength of the elastic member can be improved.

The elastic member according to the fourth embodiment includes a bendable region and a rollable region. That is, the elastic member includes a rolling region. Accordingly, the elastic member is applied to a rollable display device.

In detail, an edge region of the elastic member is bendable. That is, the elastic member includes a first region that is bent. Furthermore, one region of the elastic member is rolled. That is, the elastic member includes a second region that is rolled.

The first pattern part is formed in the first region. The reaction force of the first region is reduced by the first pattern part. Accordingly, the force acting in an opposite direction to a bending direction of the first region is reduced.

Furthermore, the second pattern part is formed in the second region. The stress in the second region is reduced by the second pattern part. Accordingly, the second region is easily rolled.

Furthermore, ratios of the pattern parts formed in the first region and the second region are different. Specifically, a ratio of the second pattern part formed in the second region is greater than the ratio of the first pattern part formed in the first region.

Therefore, the rolling characteristics and strength of the elastic member can be improved.

### DESCRIPTION OF DRAWINGS

FIG. 1 is a perspective view of a display device according to an embodiment.

FIG. 2 is a cross-sectional view of the layer structure of an elastic member according to an embodiment.

FIG. 3 is a top view of the first layer of an elastic member according to an embodiment.

FIGS. 4 to 7 are perspective views of a first layer of an elastic member according to a first embodiment.

FIGS. 8 and 9 are side views of a first layer of an elastic member according to a first embodiment.

FIG. 10 is an enlarged view of region A of FIG. 4.

FIG. 11 is a perspective view of a first layer of an elastic member according to a second embodiment.

FIGS. 12 and 13 are side views of a first layer of an elastic member according to a second embodiment before folding.

FIGS. 14 and 15 are side views of a first layer of an elastic member according to a second embodiment after folding.

FIGS. 16 and 17 are enlarged views of region B of FIG. 11.

FIG. 18 is a perspective view of the first layer of an elastic member according to a third embodiment.

FIGS. 19 and 20 are side views of a first layer of an elastic member according to a third embodiment in a first sliding mode.

FIGS. 21 and 22 are side views of a first layer of an elastic member according to a third embodiment in a second sliding mode.

FIG. 23 is an enlarged view of region C of FIG. 18.

FIG. 24 is a perspective view of a first layer of an elastic member according to a fourth embodiment.

FIGS. 25 and 26 are side views of a first layer of an elastic member according to a fourth embodiment in a first rollable mode.

FIG. 27 is a side view of a first layer of an elastic member according to a fourth embodiment in a second rollable mode.

FIG. 28 is an enlarged view of region D of FIG. 24.

FIG. 29 is a cross-sectional view of a flexible support including an elastic member according to an embodiment.

FIG. 30 is a cross-sectional view of a display device including a flexible support according to an embodiment.

FIG. 31 is a drawing illustrating an application example of a display device according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, an elastic member, a folding support and a display device including the elastic member according to an embodiment will be described with reference to drawings.

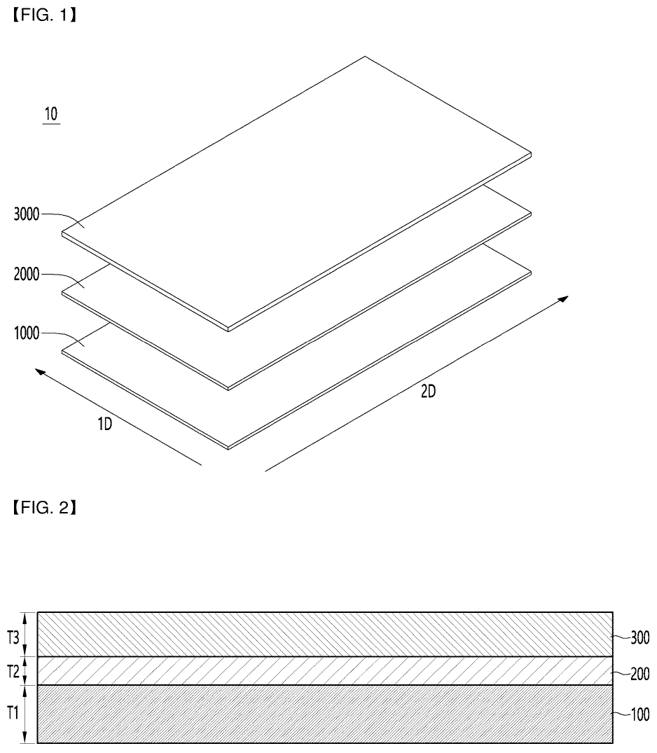

FIG. 1 is a perspective view of a display device.

Referring to FIG. 1, the display device 10 includes an elastic member 1000 and a panel. The panel may include at least one of a display panel 2000 and a touch panel 3000.

The elastic member 1000, the display panel 2000, and the touch panel 3000 may be bonded together by an adhesive layer.

The elastic member 1000 supports the display panel 2000 and the touch panel 3000. The elastic member 1000 may be a supporting substrate supporting the display panel 2000 and the touch panel 3000.

The elastic member 1000 includes at least one of a metallic material and a non-metallic material. For example, the elastic member 1000 may include a plurality of layers. The plurality of layers may include at least one of metallic and non-metallic materials.

For example, the elastic member 1000 may include at least one of a metal, a metal alloy, a plastic, a composite material (e.g., carbon fiber reinforced plastic, a magnetic or conductive material, or a glass fiber reinforced material), ceramic, sapphire, and glass.

The elastic member 1000 has elasticity. Accordingly, the elastic member 1000 can be bent in one direction. For example, the elastic member 1000 can be folded in one direction. Alternatively, an end of the elastic member 1000 can be bent in one direction. That is, the elastic member 1000 can be applied to a foldable or flexible display device.

The elastic member 1000 is defined by a first direction 1D and a second direction 2D. The first direction 1D is defined as a width direction of the elastic member 1000. The second direction 2D is different from the first direction 1D. The second direction 2D is defined as a direction perpendicular to the first direction 1D. That is, the second direction 2D is defined in a longitudinal direction of the elastic member 1000.

The display panel 2000 is disposed on the elastic member 1000.

The display panel 2000 may include a plurality of pixels, each including a switching thin film transistor, a driving thin film transistor, a capacitor, and an organic light emitting diode (OLED). The organic light emitting diode can be deposited at a relatively low temperature. Therefore, the display panel 2000 has low power consumption and high brightness, making it suitable for use in display devices. Here, a pixel refers to a minimum unit for displaying an image. The display panel displays an image through a plurality of pixels.

The display panel 2000 may include a substrate, a gate line disposed on the substrate, a data line and a common power line insulated from and intersecting the gate line. In general, one pixel may be defined as a boundary between a gate line, a data line, and a common power line.

The substrate may include a flexible material, such as a plastic film. The display panel 2000 may be formed by positioning an organic light-emitting diode and a pixel circuit on a flexible film.

The touch panel 3000 is disposed on the display panel 2000. The touch panel 3000 applies a touch function to the display device. Alternatively, a display device that only displays images without the touch function may omit the touch panel.

The touch panel 3000 includes a substrate and a touch electrode disposed on the substrate. The touch electrode can detect a position of an input device touching the display device using a capacitive or resistive method.

The substrate of the touch panel 3000 may include a flexible material, such as a plastic film. The touch panel 3000 may be implemented by arranging touch electrodes on the flexible film.

The touch panel 3000 may be formed integrally with the display panel 2000. For example, the touch panel 3000 may be formed integrally with the display panel 2000 in an on-cell or in-cell manner. Accordingly, the substrate of the touch panel 3000 may be a substrate of the display panel or a component thereof. Accordingly, the touch panel 3000 and the display panel 2000 may be formed integrally. Accordingly, a thickness of the foldable display device can be reduced.

The elastic member 1000 and the display panel 2000 may have different sizes.

For example, an area of the elastic member 1000 may be 90% or more and 110% or less of an area of the display panel 2000. Specifically, the area of the elastic member 1000 may be 95% or more and 105% or less of the area of the display panel 2000. Even more specifically, the area of the elastic member 1000 may be 97% or more and 100% or less of the area of the display panel 2000.

If the area of the elastic member 1000 is less than 90% of the area of the display panel 2000, the supporting force of the elastic member 1000 for supporting the display panel 2000 and the touch panel 3000 is reduced. Accordingly, curling may occur in an unfolding region of the elastic member 1000.

In addition, if the area of the elastic member 1000 exceeds 110% of the area of the display panel 2000, a bezel region of the display device may increase.

Meanwhile, although not shown in the drawing, a cover window may be additionally disposed above the touch panel 3000 or above the display panel 2000 (if the touch panel is omitted). The cover window may protect the display device.

Referring to FIG. 2, the elastic member 1000 may include a plurality of layers. The elastic member 1000 may include a first layer 100, a second layer 200, and a third layer 300. The first layer 100, the second layer 200, and the third layer 300 are sequentially disposed. Specifically, the second layer 200 is disposed on the first layer 100. In addition, the third layer 300 is disposed on the second layer 200.

The first layer 100 may include a metal. For example, the first layer 100 may include a metal or a metal alloy. For example, the first layer 100 may include at least one of stainless steel (SUS) and copper (Cu). Alternatively, the first layer 100 may include a copper alloy including at least one of nickel (Ni), chromium (Cr), iron (Fe), titanium (Ti), manganese (Mn), molybdenum (Mo), silver (Ag), zinc (Zn), nitrogen (N), and aluminum (Al).

Alternatively, the first layer 100 may include a base material and fibers. Specifically, the first layer 100 may include the base material and fibers disposed within the base material.

The base material accommodates the fibers. The base material supports the fibers.

The base material may include a resin material. For example, the base material may include at least one resin material selected from a group consisting of polyimide, polysulfone, polyphenylene sulfide, polyamide-imide, polyether ether ketone, liquid-crystal polyester, polyamide, polyoxymethylene, polycarbonate, polybutylene terephthalate, modified polyphenylene oxide, epoxy, and acrylate.

The fiber is disposed within the base material. For example, the fiber may be impregnated within the base material.

The fiber may include an elastic material. For example, the fiber may include at least one of carbon fiber, glass fiber, and ceramic fiber. Preferably, the fiber includes carbon fiber.

The fibers may have a predetermined length and diameter. For example, the fibers may have a diameter of 0.0001 mm to 0.01 mm. Furthermore, the length of the fibers may vary depending on a size of the base material.

When the first layer 100 includes the base material and the fibers, the second layer and the third layer may be omitted. That is, when the first layer 100 includes the base material and the fibers, the elastic member may include only the first layer.

The first layer 100 may have a predetermined thickness. The thickness T1 of the first layer 100 may be 30 μm, 50 μm, 100 μm, or 150 μm or more. For example, the thickness of the first layer 100 may be 30 μm to 200 μm.

The second layer 200 is disposed on the first layer 100.

The second layer 200 may include an adhesive. The second layer 200 may be an adhesive layer. The first layer 100 and the third layer 300 are bonded by the second layer 200.

For example, the second layer 200 may include a pressure-sensitive adhesive (PSA).

The third layer 300 may be a planarizing layer. The third layer 300 may planarize a surface of the first layer 100.

The third layer 300 may include a metal or a non-metal. For example, the third layer 300 may include a non-metal. For example, the third layer 300 may include plastic.

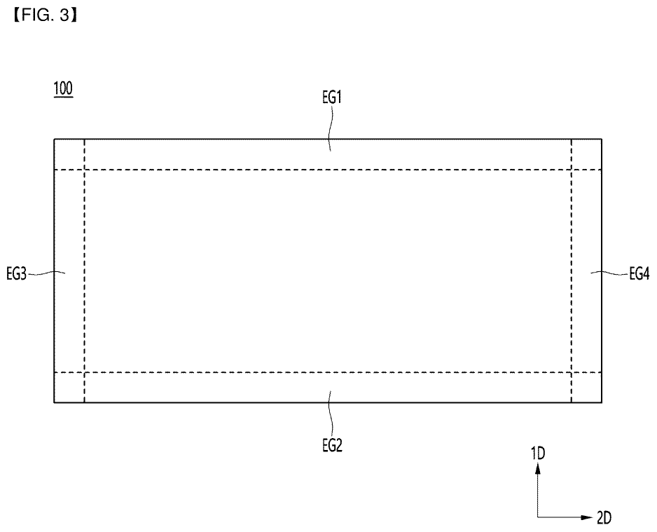

FIG. 3 is a top view of the first layer.

Referring to FIG. 3, the first layer 100 includes a plurality of edges. Specifically, the first layer 100 includes a first edge EG1, a second edge EG2, a third edge EG3, and a fourth edge EG4.

The first edge EG1 and the second edge EG2 face each other in the first direction 1D. The first edge EG1 and the second edge EG2 extend in the second direction 2D.

The third edge EG3 and the fourth edge EG4 face each other in the second direction 2D. The third edge EG3 and the fourth edge EG4 extend in the first direction 1D.

The first edge EG1, the second edge EG2, the third edge EG3, and the fourth edge EG4 are connected. The first edge EG1, the second edge EG2, the third edge EG3, and the fourth edge EG4 surround the first layer 100.

The first layer 100 may be bendable. For example, at least one edge among the first edge EG1, the second edge EG2, the third edge EG3, and the fourth edge EG4 may be bendable.

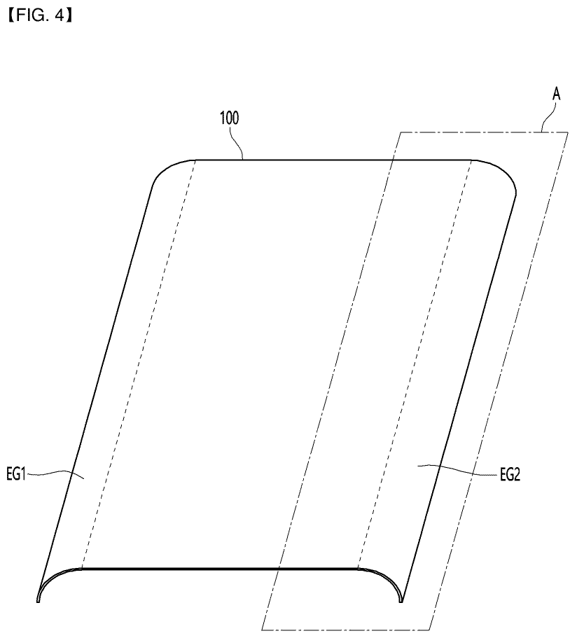

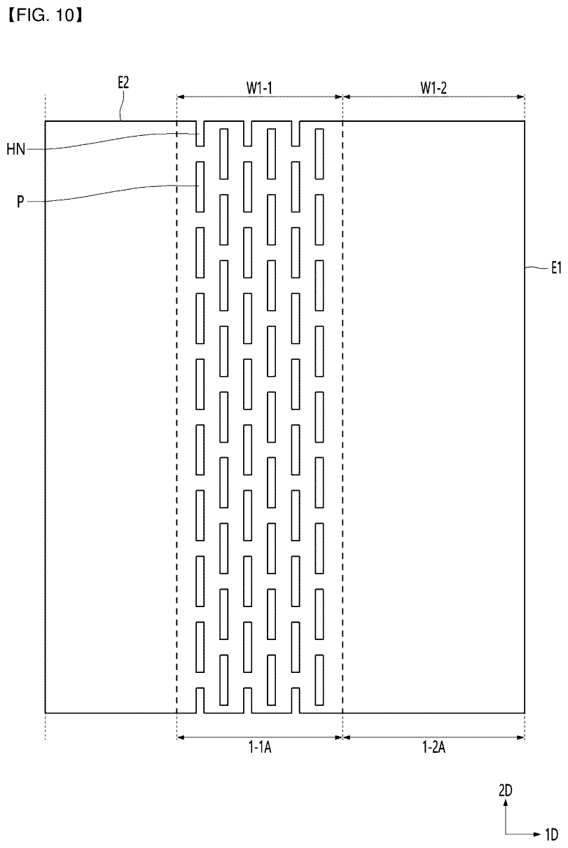

Hereinafter, an elastic member according to a first embodiment will be described with reference to FIGS. 4 to 10.

Referring to FIGS. 4 to 10, the first layer 100 is bent. Specifically, the end of the first layer 100 is bent.

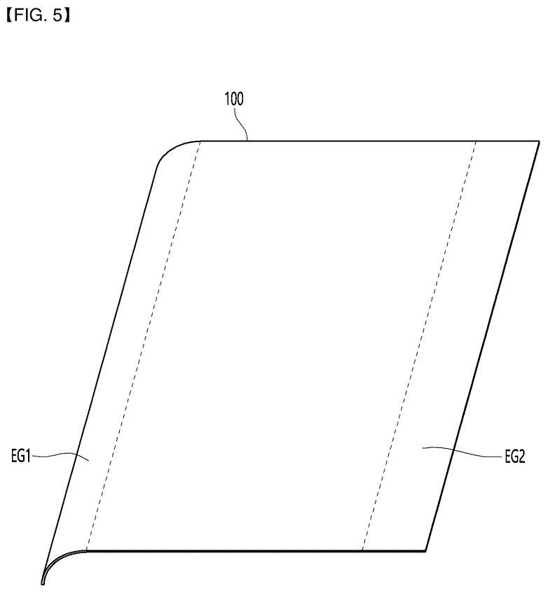

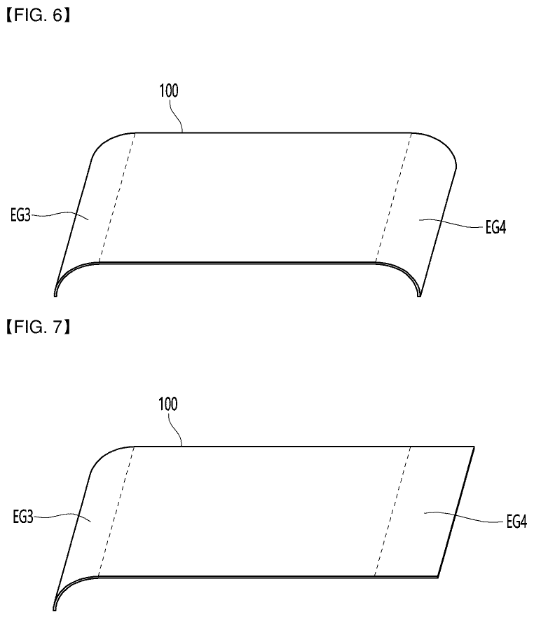

Referring to FIGS. 4 and 5, at least one edge of the first edge EG1 and the second edge EG2 may be bent. Referring to FIGS. 6 and 7, at least one edge of the third edge EG3 and the fourth edge EG4 may be bent.

However, the embodiment is not limited thereto. The first layer 100 may have at least three or more edges bent among the first edge EG1, the second edge EG2, the third edge EG3, and the fourth edge EG4. For example, all edges of the first layer 100 may be bent.

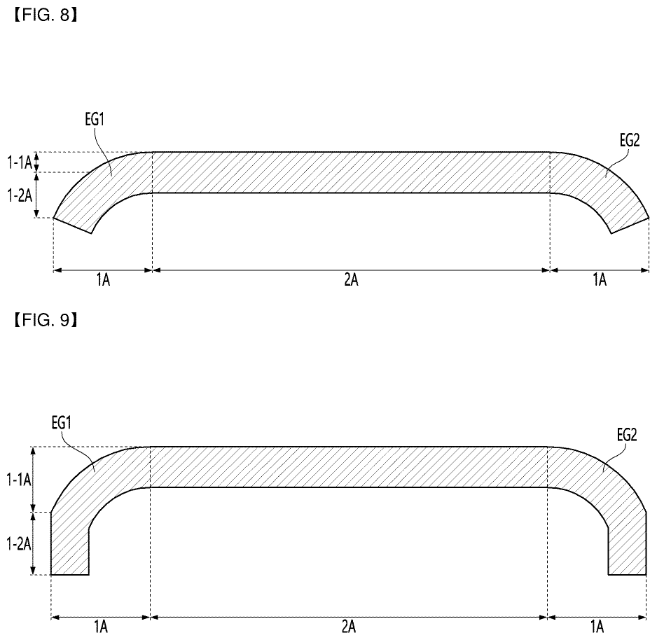

Referring to FIGS. 8 and 9, the first layer 100 includes a plurality of regions.

The first layer 100 includes a first region 1A and a second region 2A.

The first region 1A corresponds to at least one edge among the first edge EG1, the second edge EG2, the third edge EG3, and the fourth edge EG4. Specifically, the first region 1A is formed in an edge that is bent among the plurality of edges. The second region 2A is a region surrounded by the edges. In other words, the second region 2A is an inner region of the edges.

The first region 1A bends in one direction. The first region 1A is a region that is fixed in a bent state. As the first region 1A bends, an edge of the elastic member 100 also bends. Accordingly, the design freedom of the display device can be improved. In addition, the display device can be formed with various display regions. For example, the second region 2A can display a screen. In addition, the first region 1A can display a clock or an operation unit.

The first region 1A is bent. Accordingly, a reaction force may be generated in the first region 1A. The reaction force may be defined as a force that attempts to straighten the bent first region 1A. In other words, the reaction force may be defined as a force that acts in an opposite direction to a bending direction. As the reaction force increases, the adhesive strength between the first layer 100 and the second layer 200 may decrease. Specifically, a gap may be formed between the first layer 100 and the second layer 200 in the first region. In addition, it becomes difficult to dispose the second layer 200 on the first layer 100.

To solve the above problem, a pattern part P may be formed in the first region 1A.

Referring to FIGS. 8 to 10, the first region 1A includes a plurality of regions. The first region 1A includes a first-first region 1-1A and a first-second region 1-2A. The first-first region 1-1A is disposed inside the first layer 100. The first-first region 1-1A is disposed further from an end of the first layer 100 than the first-second region 1-2A. The first-first region 1-1A is disposed further from an end of an edge on which the first region of the first layer 100 is formed than the first-second region 1-2A.

For example, the first layer 100 includes a first end E1 facing in the first direction 1D and a second end E2 facing in the second direction 2D. When the first region corresponds to the first edge EG1 and the second edge EG2, the first-first region 1-1A is disposed further from the first end E1 than the first-second region 1-2A.

Alternatively, when the first region corresponds to the third edge EG3 and the fourth edge EG4, the first-first region 1-1A is disposed further from the second end E2 than the first-second region 1-2A.

At least one of the first-first region 1-1A and the first-second region 1-2A is bent. In detail, at least one of the first-first region 1-1A and the first-second region 1-2A has a curvature that is not 0. For example, when the first region 1A is bent as in FIG. 8, the first-first region 1-1A and the first-second region 1-2A are bent. Alternatively, when the first region 1A is bent as in FIG. 9, the first-first region 1-1A is bent. In addition, the first-second region 1-2A is not bent. That is, a curvature of the first-second region 1-2A is 0.

The first layer 100 includes a plurality of pattern parts P. The pattern parts P are formed in the first region 1A. Specifically, the pattern parts P are disposed in the first-first region 1-1A. The pattern parts P are formed to penetrate the first layer 100. For example, the pattern parts P may be formed in a hole shape penetrating the first layer 100. Alternatively, the pattern parts P may be formed in a groove shape partially penetrating the first layer 100. For example, the pattern parts P may be formed to penetrate 50% or more of the first layer 100. If the pattern parts P are formed to penetrate less than 50% of the first layer 100, a reaction force reduction effect by the pattern parts P is reduced.

The reaction force of the first region 1A is reduced by the pattern part P. Accordingly, adhesion failure between the first layer 100 and the second layer 200 is reduced. Consequently, the adhesion failure between the first layer 100 and the third layer 300, which are bonded by the second layer 200, is reduced.

The first region 1A may further include a hinge part HN. The hinge part HN is disposed in the first-first region 1-1A. The hinge part HN is formed by penetrating an end of the first layer 100.

For example, if the first region corresponds to the first edge EG1 and the second edge EG2, the hinge part HN is formed by penetrating the second end E2. The hinge part HN is formed to open the second end E2. The hinge part HN is formed so that the second end E2 is opened in the longitudinal direction.

Alternatively, when the first region corresponds to the third edge EG3 and the fourth edge EG4, the hinge part HN is formed to penetrate the first end E1. That is, the hinge part HN is formed to open the first end E1. The hinge part HN is formed so that the first end E1 is opened in the longitudinal direction.

The first-first region 1-1A and the first-second region 1-2A can be distinguished by the hinge part HN. That is, the first-first region 1-1A can be defined as a region where the hinge part HN is formed. The first region 1A can be easily bent by the hinge part HN.

The pattern part P is not formed in the first-second region 1-2A. Another member may be disposed on the first-second region 1-2A. For example, the elastic member 1000 may be combined with another member on the first-second region 1-2A. Alternatively, the first-second region 1-2A may be defined as a bezel region.

A size of the first-first region 1-1A may be different from a size of the first-second region 1-2A. For example, a width W1-1 of the first-first region 1-1A may be different from a width W1-2 of the first-second region 1-2A. In detail, the width W1-1 of the first-first region 1-1A may be less than or equal to the width W1-2 of the first-second region 1-2A. More specifically, the width W1-1 of the first-first region 1-1A may be 90% or more, 95% or more, or 99% or more of the width W1-2 of the first-second region 1-2A.

Since the width W1-1 of the first-first region 1-1A is less than or equal to the width W1-2 of the first-second region 1-2A, a bonding region between the elastic member and another member can be sufficiently secured. In addition, since the region where the pattern part P is formed is controlled, it is possible to prevent the strength of the first layer 100 from decreasing.

The elastic member according to the first embodiment includes a bendable region. Specifically, the edge region of the elastic member is bent. That is, the elastic member includes a first region that is bent.

The pattern part is formed in the first region. The reaction force of the first region is reduced by the pattern part. Consequently, the force acting in an opposite direction of a bending direction of the first region is reduced.

Therefore, the stress generated in the first region is reduced. Accordingly, the adhesion between the first layer and the second layer is improved. Furthermore, a bent shape of the first region is maintained. Therefore, the reliability of the elastic member is improved. Furthermore, the design freedom of the elastic member is enhanced.

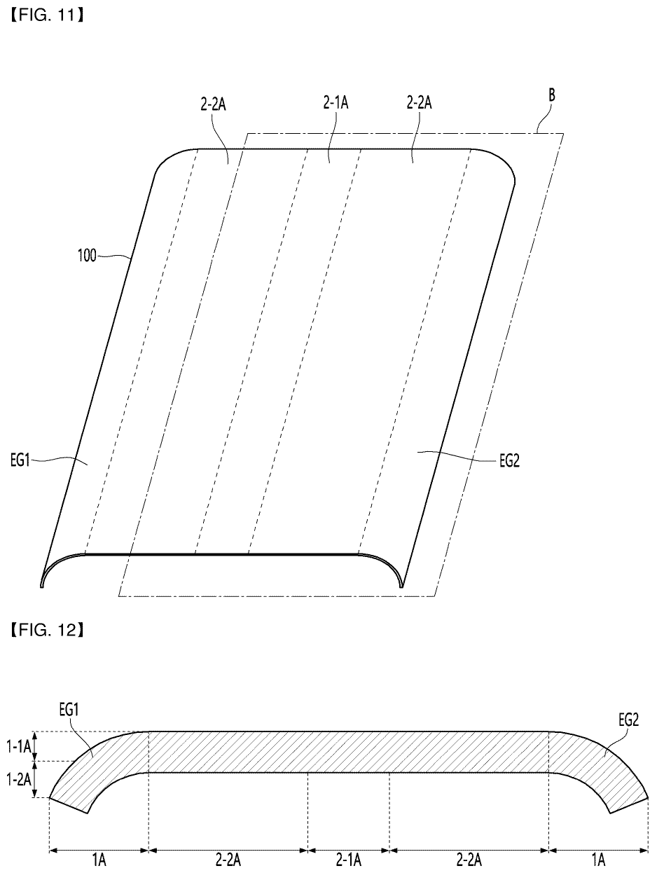

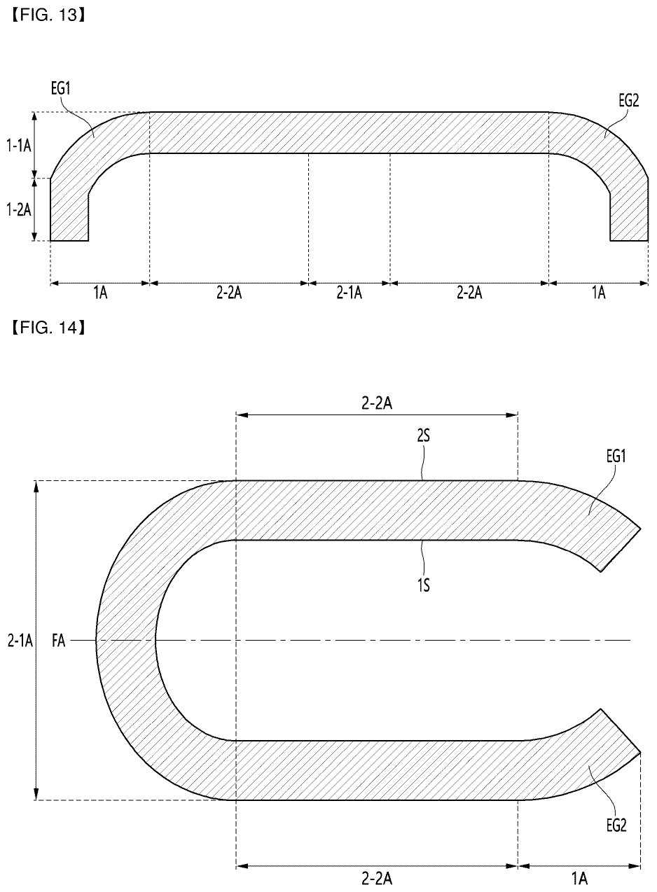

Hereinafter, an elastic member according to a second embodiment will be described with reference to FIGS. 11 to 17. Descriptions identical to those of the first embodiment will be omitted. Same reference numerals are used for components identical to those of the first embodiment.

Referring to FIGS. 11 to 13, the first layer 100 is bent. In addition, the first layer 100 can be folded. Specifically, the first region 1A is bent. In addition, the second region 2A includes a folding region.

The first region 1A includes a plurality of regions. The first region 1A includes a first-first region 1-1A and a first-second region 1-2A. The first region 1A is identical to the first embodiment. Therefore, a detailed description thereof will be omitted.

The second region 2A includes a second-first region 2-1A and a second-second region 2-2A. A plurality of second-second regions 2-2A are disposed on left and right sides of the second-first region 2-1A. The second-first region 2-1A is positioned between the plurality of second-second regions 2-2A.

The second-first region 2-1A can be folded. Therefore, the second-first region 2-1A is defined as a folding region. The second-second region 2-2A is not folded. Therefore, the second-second region 2-2A is defined as an unfolding region.

Sizes of the second-first region 2-1A and the second-second region 2-2A may differ. For example, an area of the second-second region 2-2A may be larger than that of the second-first region 2-1A.

For example, the area of the second-first region 2-1A may be 1% to 30% of the area of the second region. Specifically, the area of the second-first region 2-1A may be 5% to 20% of the area of the second region. In more detail, the area of the second-first region 2-1A may be 10% to 15% of the area of the second region.

If the area of the second-first region 2-1A is less than 1% of the area of the second region, cracks may occur at an interface between the folding region and the unfolding region. Accordingly, the folding reliability of the elastic member 1000 may be reduced.

Furthermore, if the area of the second-first region 2-1A exceeds 30% of the area of the second region, curling may occur in the first region 1A when folding the elastic member.

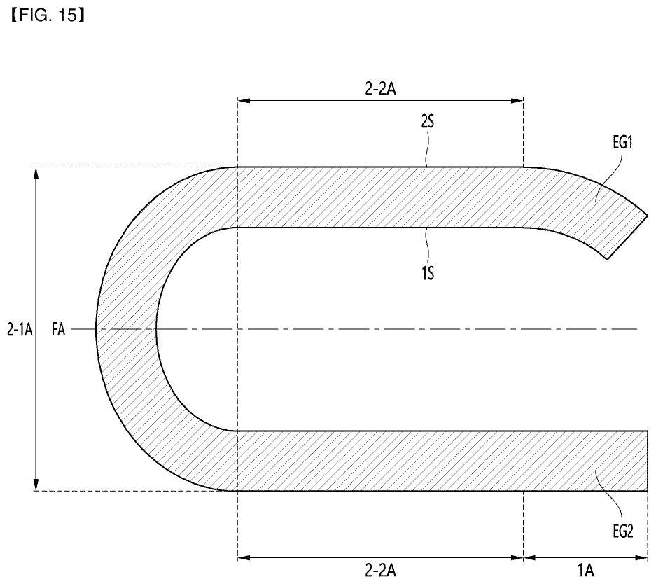

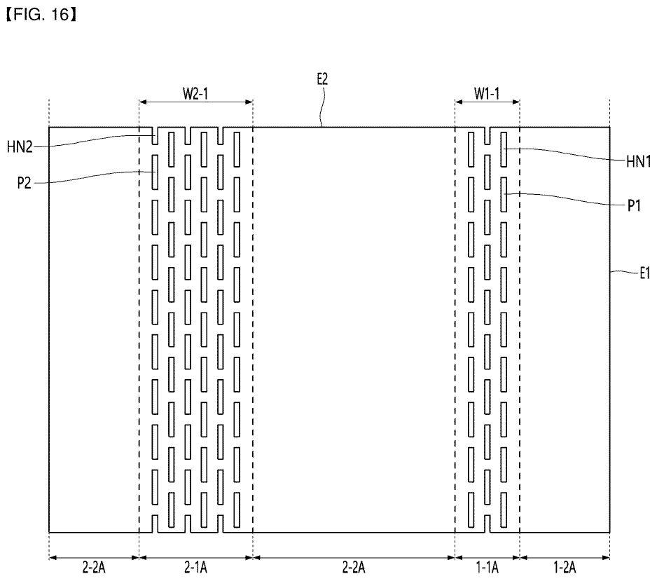

Referring to FIGS. 14 and 15, the first layer 100 can be folded. Specifically, the second-first region 2-1A can be folded. Specifically, the first layer 100 is bent in one direction with respect to a folding axis. For example, the first layer 100 includes a first surface 1S and a second surface 2S. The first layer 100 may be folded in a direction in which the first surface IS faces.

Unlike the first region 1A, the second region 2-1A is not a fixed region. That is, the 2-1 region 2-1A is repeatedly folded and unfolded. Accordingly, the second region 2-1A has a curvature when the first layer 100 is folded.

When the second region 2-1A is folded, stress is generated in the second region 2-1A. That is, compressive stress is generated on a folding inner surface, and tensile stress is generated on a folding outer surface. Accordingly, cracks may occur in the second-first region 2-1A. Furthermore, as folding is repeated, a crease may occur in the second-first region 2-1A.

To address the above-described problem, a pattern part may be formed in the second-first region 2A.

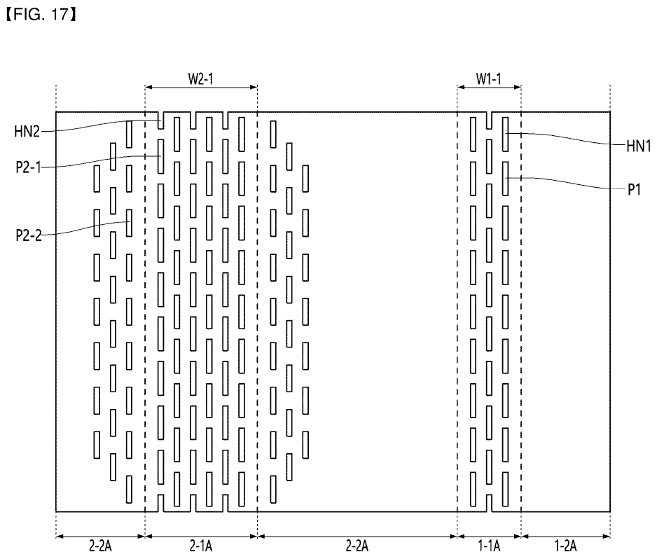

Referring to FIGS. 16 and 17, the first layer 100 includes a first pattern part P1 and a second pattern part P2.

The first pattern part P1 is disposed in the first-first region 1-1A. Since the first pattern part P1 is the same as in the first embodiment, the description of the first pattern part will be omitted.

The second pattern part P2 is disposed in the second-first region 2-1A. The second pattern part P2 is formed to penetrate the first layer 100. For example, the second pattern part P2 may be formed in a hole shape penetrating the first layer 100. Alternatively, the second pattern part P2 may be formed in a groove shape partially penetrating the first layer 100. For example, the second pattern part P2 may be formed by penetrating the first layer 100 by more than 50%.

The stress of the second-first region 2-1A is reduced by the second pattern part P2. Accordingly, when the first layer 100 is folded and unfolded, cracks or crease can be prevented from occurring in the second-first region 2-1A.

The first layer 100 includes a hinge part. The hinge part includes a first hinge part HN1 and a second hinge part HN2. The first hinge part HN1 is disposed in the first-first region 1-1A. The first hinge part HN1 is identical to the first embodiment. Therefore, a detailed description thereof will be omitted.

The second hinge part HN2 is disposed in the second-first region 2-1A. The hinge part HN is formed by penetrating the end of the first layer 100.

For example, if the first region corresponds to the first edge EG1 and the second edge EG2, the second hinge part HN2 is formed by penetrating the second end E2. Alternatively, if the first region corresponds to the third edge EG3 and the fourth edge EG4, the second hinge part HN is formed by penetrating the second end E2.

That is, the second hinge part HN2 is formed by penetrating the second end E2, regardless of a region where the edges are bent.

The second-first region 2-1A and the second-second region 2-2A can be distinguished by the second hinge part HN2. That is, the second-first region 1-1A can be defined as a region where the hinge part HN is formed. The second-first region 2-1A can be easily bent by the second hinge part HN2.

Referring to FIG. 16, the second pattern part P2 may not be formed in the second-second region 2-2A. Accordingly, the strength of the first layer 100 can be improved. The second pattern part P2 is formed by removing the second layer. Accordingly, as the area of the second pattern part P2 increases, the strength of the first layer 100 may decrease. Accordingly, the second pattern part P2 may be formed only in the second-first region 2-1A.

Alternatively, referring to FIG. 17, the second pattern part P2 may also be formed in the second-second region 2-2A. Specifically, a second-first pattern part P2-1 may be formed in the second-first region 2-1A, and a second-second pattern part P2-2 may be formed in the second-second region 2-2A.

A size of the second-second pattern part P2-2 may vary depending on locations. Specifically, a size of the second-second pattern part P2-2 may decrease as it moves away from the second-first region 2-1A. That is, the second-second pattern part P2-2 may be a gradient pattern.

If the second pattern part is disposed only in the second-first region 2-1A, a stress difference between the second-first region 2-1A and the second-second region 2-2A may increase. Accordingly, cracks may occur at a boundary between the second-first region 2-1A and the second-second region 2-2A. Therefore, a pattern part is also disposed in the second-second region 2-2A. Accordingly, the stress difference between the second-first region 2-1A and the second-second region 2-2A decreases. Therefore, cracks may be prevented from occurring at the boundary between the second-first region 2-1A and the second-second region 2-2A.

The first pattern part P1 and the second pattern part P2 may be disposed with different sizes. Furthermore, the first pattern part P1 and the second pattern part P2 may be disposed with different spacings.

For example, the size of the second pattern part P2 may be larger than that of the first pattern part P1. That is, an opening area of the second pattern part P2 may be larger than that of the first pattern part P1.

Alternatively, a spacing of the second pattern part P2 in the first direction may be smaller than a spacing of the first pattern part P1 in the first direction. Alternatively, the spacing of the second pattern part P2 in the second direction may be smaller than the spacing of the first pattern part P1 in the second direction.

In addition, a ratio of the area of the second pattern part PA2 to the total area of the second-first region 2-1A may be greater than a ratio of the area of the first pattern part PA1 to the total area of the first-first region 1-1A.

The second-first region 2-1A undergoes repeated folding and unfolding. In addition, the second-first region 2-1A is bent at a greater curvature than the first-first region 1-1A. Accordingly, the stress generated in the second-first region 2-1A is greater than the stress generated in the first-first region 1-1A. Accordingly, the first layer 100 forms pattern parts at different ratios depending on the location. That is, more pattern parts are formed in the second-first region 2-1A than in the first-first region 1-1A. Accordingly, the first layer 100 can have improved folding characteristics and strength.

A size of the first-first region 1-1A and a size of the second-first region 2-1A may differ. For example, a width W2-1 of the second-first region 2-1A may differ from a width W1-1 of the first-first region 1-1A. Specifically, the width W2-1 of the second-first region 2-1A is greater than the width W1-1 of the first-first region 1-1A.

Since the second-first region 2-1A is a region for folding the first layer 100, the width of the second-first region 2-1A is formed to be greater than the width of the first-first region. Consequently, the first layer 100 can be easily folded in one direction.

An elastic member according to a second embodiment includes a bendable region and a foldable region. Specifically, the elastic member includes a folding region. Accordingly, the elastic member is applied to a foldable display device.

In detail, an edge region of the elastic member is bent. That is, the elastic member includes a first region that is bent. In addition, an inner region of the elastic member is foldable. That is, the elastic member includes a second region that is folded.

The first pattern part is formed in the first region. The reaction force of the first region is reduced by the first pattern part. Accordingly, the force acting in an opposite direction of a bending direction of the first region is reduced.

Furthermore, the second pattern part is formed in the second region. The stress of the second region is reduced by the second pattern part. Accordingly, the second region is easily folded.

Furthermore, ratios of pattern parts formed in the first region and the second region are different. Specifically, a ratio of the second pattern part formed in the second region is greater than a ratio of the first pattern part formed in the first region.

Therefore, the folding characteristics and strength of the elastic member can be improved.

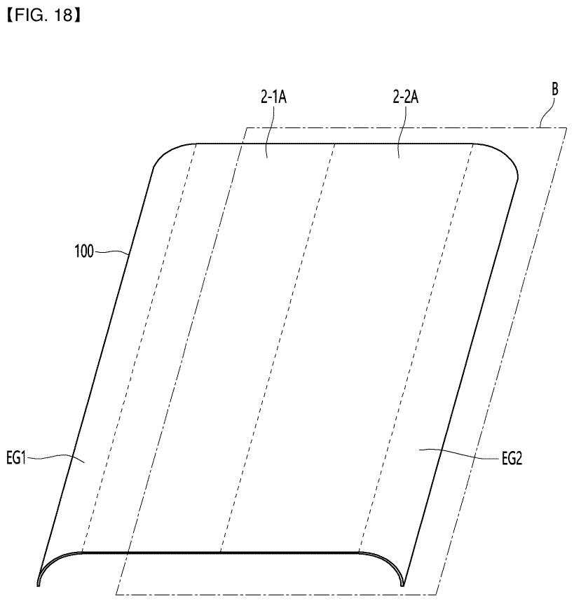

Hereinafter, an elastic member according to a third embodiment will be described with reference to FIGS. 18 to 23. Descriptions identical to those of the first embodiment will be omitted. The same reference numerals will be used for components identical to those of the first embodiment.

Referring to FIGS. 18 to 22, the first layer 100 is bendable. Furthermore, the first layer 100 can slide. Specifically, the first region 1A is bendable. Furthermore, the second region 2A includes a sliding region.

The first region 1A includes a plurality of regions. The first region 1A includes a first-first region 1-1A and a first-second region 1-2A. The first region 1A is identical to the first embodiment. Therefore, a detailed description thereof will be omitted.

The second region 2A includes a second-first region 2-1A and a second-second region 2-2A. The second-second region 2-2A is disposed on one side of the second-first region 2-1A. Specifically, the second-second region 2-2A is positioned on a left or right side of the second-first region 2-1A.

The second-first region 2-1A can bend. Therefore, the second-first region 2-1A is defined as a sliding region. The second-second region 2-2A is not bent. Therefore, the second-second region 2-2A is defined as an un-sliding region.

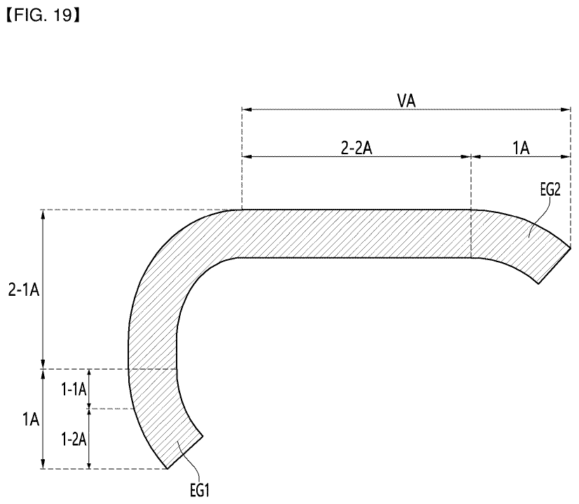

Referring to FIGS. 19 to 22, a size of the screen region VA of the first layer 100 may vary depending on the size of the second-first region 2-1A.

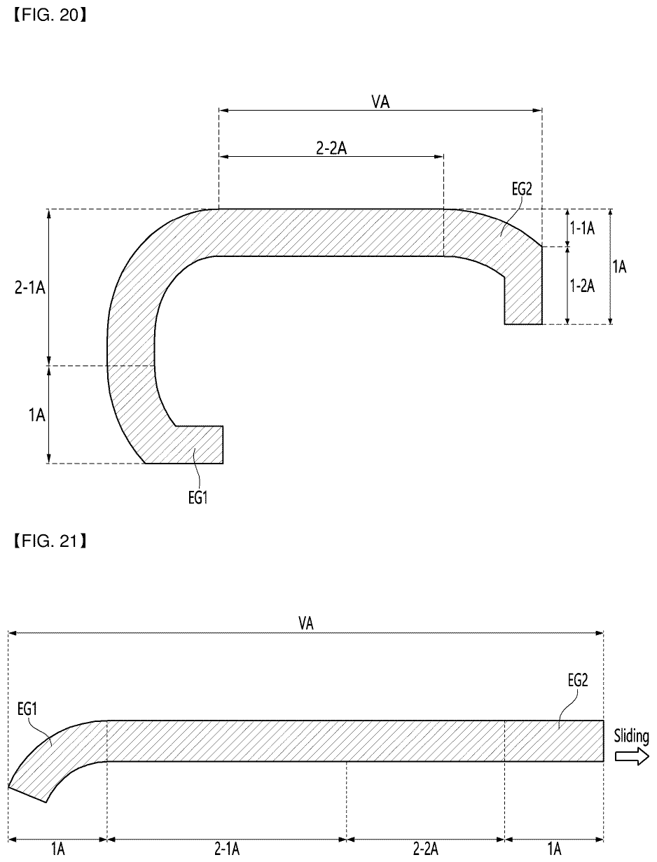

Referring to FIGS. 19 and 20, the second-first region 2-1A slides in a first sliding mode. The second-first region 2-1A does not display a screen in the first sliding mode.

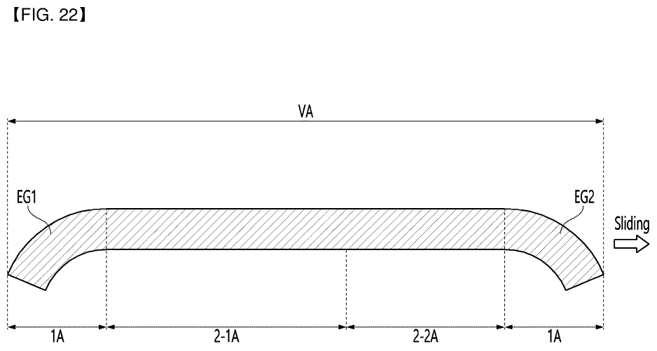

Referring to FIGS. 21 and 22, the second-first region 2-1A slides in a second sliding mode. The second-first region 2-1A displays a screen in the second sliding mode.

Therefore, the second-first region 2-1A selectively displays a screen, and the second-second region 2-2A always displays a screen.

If the user wishes to use a narrow screen region, the screen is displayed in the first sliding mode. In addition, if the user desires to use a wider screen region, the screen is displayed in the second sliding mode. Accordingly, the user can use various screen regions according to the desired mode.

Unlike the first region 1A, the second region 2-1A is not a fixed region. That is, the second region 2-1A is repeatedly slid. Consequently, the second region 2-1A has a curvature in the first sliding mode.

As the sliding mode is repeated, stress is generated in the second region 2-1A. Accordingly, cracks may occur in the second region 2-1A. Furthermore, as the sliding is repeated, a crease may occur in the second region 2-1A.

To solve the above problems, a pattern part may be formed in the second region 2A.

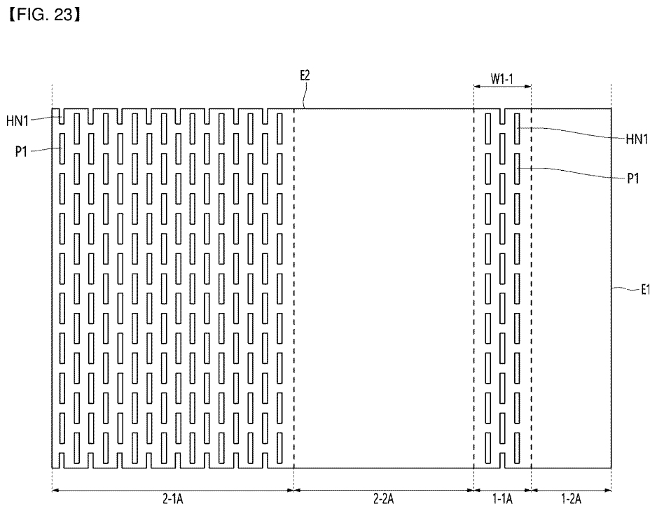

Referring to FIG. 23, the first layer 100 includes a first pattern part P1 and a second pattern part P2.

The first pattern part P1 is disposed in the first-first region 1-1A. Since the first pattern part P1 is the same as in the first embodiment, the description of the first pattern part will be omitted.

The second pattern part P2 is disposed in the second-first region 2-1A. The second pattern part P2 is formed penetrating the first layer 100. For example, the second pattern part P2 may be formed in a hole shape penetrating the first layer 100. Alternatively, the second pattern part P2 may be formed in a groove shape partially penetrating the first layer 100. For example, the second pattern part P2 may be formed penetrating the first layer 100 by 50% or more.

The stress in the second-first region 2-1A is reduced by the second pattern part P2. Accordingly, when the first layer 100 slides, cracks or crease can be prevented from occurring in the second-first region 2-1A.

The first layer 100 includes a hinge part. The hinge part includes a first hinge part HN1 and a second hinge part HN2. The first hinge part HN1 is disposed in the first-first region 1-1A. The first hinge part HN1 is the same as that of the first embodiment. Therefore, the following description is omitted.

The second hinge part HN2 is disposed in the second-first region 2-1A. The hinge part HN is formed by penetrating the end of the first layer 100.

For example, when the first region corresponds to the first edge EG1 and the second edge EG2, the second hinge part HN2 is formed by penetrating the second end E2. Alternatively, when the first region corresponds to the third edge EG3 and the fourth edge EG4, the second hinge part HN is formed by penetrating the second end E2.

That is, the second hinge part HN2 is formed by penetrating the second end E2, regardless of the region where the edges are bent.

The second-first region 2-1A and the second-second region 2-2A can be distinguished by the second hinge part HN2. That is, the second-first region 1-1A can be defined as the region where the hinge part HN is formed. The second-first region 2-1A can be easily slid by the second hinge part HN2.

The second pattern part P2 may not be formed in the second-second region 2-2A. Accordingly, the strength of the first layer 100 can be improved. The second pattern Part P2 is formed by removing the second layer. Therefore, as the area of the second pattern part P2 increases, the strength of the first layer 100 may decrease. Accordingly, the second pattern part P2 may be formed only in the second-first region 2-1A.

The first pattern part P1 and the second pattern part P2 may be disposed with different sizes. Furthermore, the first pattern part P1 and the second pattern part P2 may be disposed with different spacings.

For example, a size of the second pattern part P2 may be larger than that of the first pattern part P1. That is, an opening area of the second pattern part P2 may be larger than that of the first pattern part P1.

Alternatively, a spacing of the second pattern part P2 in the first direction may be greater than that of the first pattern part P1. Alternatively, a spacing in the second direction of the second pattern part P2 may be smaller than a spacing in the second direction of the first pattern part P1.

In addition, a ratio of an area of the second pattern part PA2 to a total area of the second-first region 2-1A may be greater than a ratio of an area of the first pattern part PA1 to a total area of the first-first region 1-1A.

The second-first region 2-1A repeatedly slides. In addition, the second-first region 2-1A is bent with a greater curvature than the first-first region 1-1A. Accordingly, the stress generated in the second-first region 2-1A is greater than the stress generated in the first-first region 1-1A. Accordingly, the first layer 100 has pattern parts formed at different ratios depending on the location. That is, more pattern parts are formed in the second-first region 2-1A than in the first-first region 1-1A. Therefore, the first layer 100 can have improved folding characteristics and strength.

A size of the first-first region 1-1A and a size of the second-first region 2-1A may be different. For example, a width W2-1 of the second-first region 2-1A and a width W1-1 of the first-first region 1-1A may be different. Specifically, the width W2-1 of the second-first region 2-1A is larger than the width W1-1 of the first-first region 1-1A.

Since the second-first region 2-1A is a region that slides the first layer 100, a width of the second-first region 2-1A is formed to be larger than a width of the first-first region 1-1A. As a result, the first layer 100 is easily slid in one direction.

An elastic member according to a third embodiment includes a foldable region and a bendable region. That is, the elastic member includes a sliding region. Accordingly, the elastic member is applied to a slidable display device.

In detail, an edge region of the elastic member is bent. That is, the elastic member includes a first region that is bent. Furthermore, one region of the elastic member is slid. That is, the elastic member includes a second region that is slid.

The first pattern part is formed in the first region. The reaction force of the first region is reduced by the first pattern part. Accordingly, the force acting in an opposite direction to a bending direction of the first region is reduced.

Furthermore, the second pattern part is formed on the second region. The stress of the second region is reduced by the second pattern part. Accordingly, the second region is easily slidable.

Furthermore, ratios of the pattern parts formed on the first region and the second region are different. Specifically, the ratio of the second pattern part formed in the second region is greater than the ratio of the first pattern part formed in the first region.

Therefore, the sliding characteristics and strength of the elastic member can be improved.

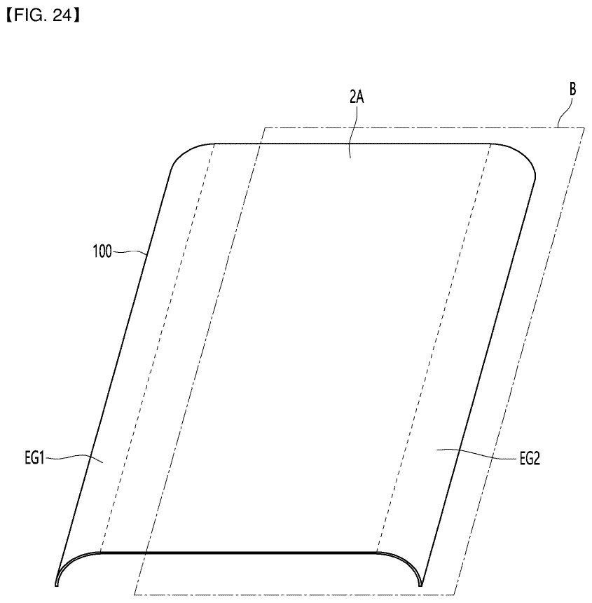

Hereinafter, an elastic member according to a fourth embodiment will be described with reference to FIGS. 24 to 28. Descriptions identical to those of the first embodiment will be omitted. Same reference numerals will be used for the same components as those of the first embodiment.

Referring to FIGS. 24 to 27, the first layer 100 is bent. Furthermore, the first layer 100 can be bent. Specifically, the first region 1A is bent. Furthermore, the second region 2A includes a rolling region.

The first region 1A includes a plurality of regions. The first region 1A includes a first-first region 1-1A and a first-second region 1-2A. The first region 1A is identical to that of the first embodiment. Therefore, the following description will be omitted.

The second region 2A can be bent. Accordingly, the second region 2A is defined as a rolling region.

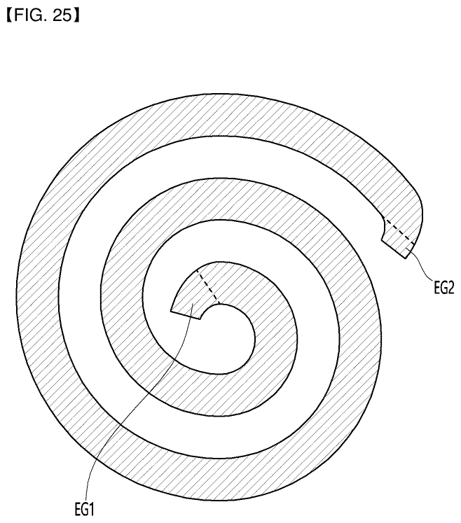

Referring to FIGS. 25 to 27, a size of the screen region VA of the first layer 100 may vary depending on the second region 2A.

Referring to FIGS. 25 and 26, the second region 2A rolls in a first rolling mode. The second region 2-1A does not display a screen in the first rolling mode.

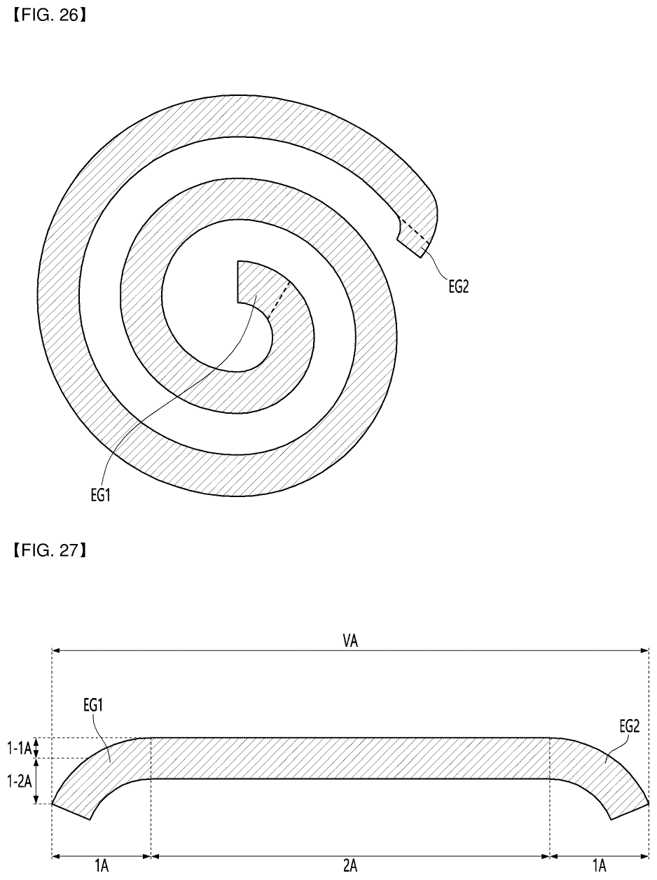

Referring to FIG. 27, the second region 2A rolls in a second rolling mode. The second region 2A displays a screen in the second rolling mode.

Therefore, the second region 2A selectively displays a screen.

If the user does not wish to use the screen region, it rolls in the first rolling mode. This allows the user to easily carry or store the display device. In addition, if the user wishes to use the screen region, it rolls in the second rolling mode. Accordingly, the user can use the screen region via the display device.

Unlike the first region 1A, the second region 2A is not a fixed region. That is, the second region 2A is repeatedly rolled. As a result, the second-first region 2-1A has a curvature in the first rolling mode.

As the rolling mode is repeated, stress is generated in the second region 2A. Consequently, cracks may occur in the second region 2A. Furthermore, as the rolling is repeated, a crease may occur in the second region 2A.

To address the above-described problem, a pattern part may be formed in the second region 2A.

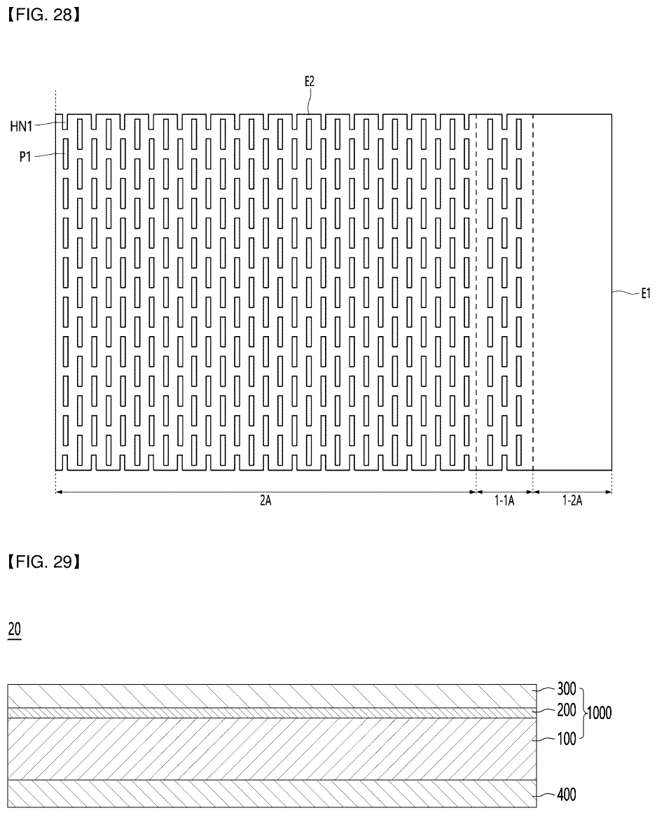

Referring to FIG. 28, the first layer 100 includes a first pattern part P1 and a second pattern part P2.

The first pattern part P1 is disposed in the first-first region 1-1A. Since the first pattern part P1 is the same as in the first embodiment, the description of the first pattern part will be omitted.

The second pattern part P2 is disposed in the second-first region 2-1A. The second pattern part P2 is formed to penetrate the first layer 100. For example, the second pattern part P2 may be formed in a hole shape penetrating the first layer 100. Alternatively, the second pattern part P2 may be formed in a groove shape partially penetrating the first layer 100. For example, the second pattern part P2 may be formed to penetrate the first layer 100 by 50% or more.

The stress in the second region 2A is reduced by the second pattern part P2. Accordingly, when the first layer 100 is rolled, cracks or crease can be prevented from occurring in the second region 2A.

The first layer 100 includes a hinge part. The hinge part includes a first hinge part HN1 and a second hinge part HN2. The first hinge part HN1 is disposed in the first-first region 1-1A. The first hinge part HN1 is the same as that of the first embodiment. Therefore, the following description is omitted.

The second hinge part HN2 is disposed in the second region 2A. The hinge part HN is formed by penetrating the end of the first layer 100.

For example, when the first region corresponds to the first edge EG1 and the second edge EG2, the second hinge part HN2 is formed by penetrating the second end E2. Alternatively, when the first region corresponds to the third edge EG3 and the fourth edge EG2. When corresponding to the edge EG4, the second hinge part HN2 is formed by penetrating the second end E2.

That is, the second hinge part HN2 is formed by penetrating the second end E2, regardless of the region where the edges are bent.

The second region 2A can be easily rolled by the second hinge part HN2.

The first pattern part P1 and the second pattern part P2 may be disposed with different sizes. Furthermore, the first pattern part P1 and the second pattern part P2 may be disposed at different spacings.

For example, the size of the second pattern part P2 may be larger than that of the first pattern part P1. That is, the opening area of the second pattern part P2 may be larger than that of the first pattern part P1.

Alternatively, the second pattern in the first direction spacing of the part P2 may be smaller than spacing in the first direction of the first pattern part P1. Alternatively, the spacing in the second direction of the second pattern part P2 may be smaller than the spacing in the second direction of the first pattern part P1.

In addition, the ratio of the area of the second pattern part PA2 to the total area of the second region 2A may be larger than the ratio of the area of the first pattern part PA1 to the total area of the first-first region 1-1A.

The second region 2A is repeatedly rolled. In addition, the second region 2A is bent with a greater curvature than the first-first region 1-1A. Accordingly, the stress generated in the second region 2A is larger than the stress generated in the first-first region 1-1A. Accordingly, the first layer 100 includes pattern parts formed at different ratios depending on the location. That is, the second region 2A has more pattern parts formed than the first-first region 1-1A. Therefore, the first layer 100 can have improved rolling characteristics and strength.

The elastic member according to the fourth embodiment includes a bendable region and a rollable region. That is, the elastic member includes a rolling region. Accordingly, the elastic member is applied to a rollable display device.

In detail, an edge region of the elastic member is bendable. That is, the elastic member includes a first region that is bent. Furthermore, one region of the elastic member is rolled. That is, the elastic member includes a second region that is rolled.

The first pattern part is formed in the first region. The reaction force of the first region is reduced by the first pattern part. Accordingly, the force acting in an opposite direction to a bending direction of the first region is reduced.

Furthermore, the second pattern part is formed in the second region. The stress in the second region is reduced by the second pattern part. Accordingly, the second region is easily rolled.

Furthermore, ratios of the pattern parts formed in the first region and the second region are different. Specifically, a ratio of the second pattern part formed in the second region is greater than the ratio of the first pattern part formed in the first region.

Therefore, the rolling characteristics and strength of the elastic member can be improved.

Hereinafter, a flexible support 20 including an elastic member according to an embodiment will be described with reference to FIG. 29.

Referring to FIG. 29, the flexible support 20 includes an elastic member 1000 and a protective layer 400.

The protective layer 400 is disposed below the elastic member 400. For example, an adhesive layer is disposed between the protective layer 400 and the elastic member 1000. The elastic member 1000 and the protective layer 400 can be bonded by the adhesive layer.

The protective layer 400 may have a color. For example, the protective layer 400 may have a black color.

The protective layer 400 may include metal particles. For example, the protective layer 400 may include copper particles. Accordingly, the thermal conductivity of the protective layer 400 can be improved. Therefore, heat generated in the display device can be dissipated by the protective layer 400.

A thickness of the protective layer 400 may be smaller than a total thickness of the elastic member 1000. That is, a thickness of the protective layer 400 may be smaller than a sum of thicknesses of the first, second, and third layers of the elastic member 400.

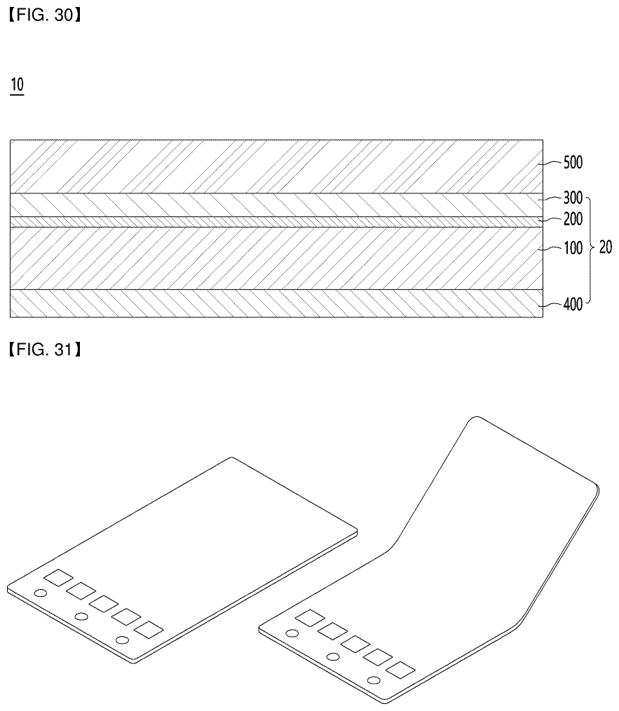

Hereinafter, a display device including a flexible support according to an embodiment will be described with reference to FIG. 30.

Referring to FIG. 30, the display device 10 may include the flexible support 20 and a panel layer 500.

The panel layer 500 may include at least one of the display panel and the touch panel.

An adhesive layer may be disposed between the flexible support 20 and the panel layer 500. The flexible support 20 and the panel layer 500 can be bonded by the adhesive layer.

The elastic member 1000 may planarize an adhesive surface of the elastic member by a third layer 300. Therefore, the elastic member and the panel layer can be easily bonded.

FIG. 31 is a drawing illustrating an application example of a display device according to an embodiment.

Referring to FIG. 31, the elastic member according to embodiments can be applied to a flexible or foldable display device that displays a display.

For example, the elastic member according to embodiments can be applied to a flexible display device including a mobile phone or tablet. As a result, the display device can be collapsed or folded.

The display device can be easily folded by the elastic member. Furthermore, the folding reliability of the display device can be improved.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. An elastic member comprising:
a first layer including a first edge region, a second edge region, a third edge region, and a fourth edge region,
wherein the first and second edge regions face each other in a first direction,
wherein the third and fourth edge regions are provided in the first and second edge regions and face each other in a second direction perpendicular to the first direction,
wherein at least one edge region among the plurality of edges regions is an bent edge region,
wherein the first layer includes a first region corresponding to the bent edge region and a second region surrounded by the first to fourth edge regions and provided inside the first to fourth edge regions, and
wherein the first region is provided with a plurality of pattern parts in which at least a part of the first layer is opened from one surface of the first layer toward the other surface of the first layer.

2. The elastic member of claim 1, further comprising:
a second layer disposed on the first layer; and
a third layer disposed on the second layer.

3. The elastic member of claim 1, wherein the first region includes a first-first region and a first-second region, depending on a distance from a first end of the bent edge region,
wherein the first-first region is located further from the first end than the first-second region, and
wherein the first layer is bent in at least one of the first-first region and the first-second region.

4. The elastic member of claim 3, wherein the pattern part is provided in the first-first region.

5. The elastic member of claim 3, wherein a width of the first-first region and a width of the first-second region are different.

6. The elastic member of claim 3, wherein the first-first region is spaced apart from the first end in a first direction with the first-second region interposed therebetween,
wherein the first-first region includes a second end and a third end positioned in a second direction different from the first direction, and
wherein the first-first region includes a hinge part in which at least one of the second end and the third end is open.

7. The elastic member of claim 1, wherein the pattern part is formed by penetrating at least 50% of the first layer.

8. The elastic member of claim 4, wherein the second region includes a second-first region and a second-second region,
wherein the second-first region is positioned between a plurality of second-second regions,
wherein the first-first region includes a first pattern part, and
wherein the second-first region includes a second pattern part.

9. The elastic member of claim 8, wherein a ratio of an area of the second pattern part to an total area of the second-first region is greater than a ratio of an area of the first pattern part to an total area of the first-first region.

10. The elastic member of claim 8, wherein a second-first pattern part is disposed in the second-first region,
wherein a second-second pattern part is disposed in the second-second region, and
wherein a size of the second-second pattern part decreases as it moves away from the second-first region.

11. The elastic member of claim 1, wherein the first layer includes a base material and a fiber disposed in the base material.

12. The elastic member of claim 2, wherein the first layer, the second layer, and the third layer include materials different from each other.

13. The elastic member of claim 12, wherein the first layer includes a metal,
wherein the second layer includes an adhesive layer, and
wherein the third layer includes a plastic.

14. The elastic member of claim 4,
The second region includes a second-first region and a second-second region,
wherein the second-first region is defined as a sliding region,
wherein a first pattern part is disposed in the first-first region, and
wherein a second pattern part is disposed in the second-first region.

15. The elastic member of claim 14, wherein a ratio of an area of the second pattern part to a total area of the second-first region is greater than a ratio of an area of the first pattern part to a total area of the first-first region.

16. The elastic member of claim 4, wherein the second region is defined as a rolling region,
wherein a first pattern part is disposed in the first-first region,
wherein a second pattern part is disposed in the second region.

17. The elastic member of claim 16, wherein a ratio of an area of the second pattern part to a total area of the second-first region is greater than a ratio of an area of the first pattern part to a total area of the first-first region.

18. A flexible support comprising:
an elastic members of claim 1; and
a protective layer disposed under the elastic member.

19. A display device comprising:
an elastic member of claim 1;
a protective layer disposed under the elastic member; and
a panel layer disposed on the elastic member,
wherein the panel layer includes at least one of a display panel and a touch panel.
